(19) United States
(12) Patent Application Publication
(10) Pub. No.: US 2014/0347083 A1
(43) Pub. Date: Nov. 27, 2014

(54) SILICON-ON-INSULATOR (SOI) BODY-CONTACT PASS GATE STRUCTURE

(71) Applicant: International Business Machines Corporation, Armonk, NY (US)

(72) Inventors: Andres Bryant, Burlington, VT (US); Edward J. Nowak, Essex Junction, VT (US); Robert R. Robison, Colchester, VT (US)

(21) Appl. No.: 14/458,459

(22) Filed: Aug. 13, 2014

Related U.S. Application Data
(62) Division of application No. 12/938,440, filed on Nov. 3, 2010.

(51) Int. Cl. H01L 21/66; H01L 27/12; G01R 31/26; H01L 29/78

(52) U.S. Cl. CPC H01L 22/32; H01L 29/7841; H01L 27/1203; G01R 31/2644; G01R 31/2621
USPC 324/754.03; 257/48; 324/762.09

(57) ABSTRACT

A circuit for testing a floating body field-effect transistor (FET), and a related method, are provided. Embodiments of this invention include a circuit including a contacted-body FET structure that can be operated in a floating body mode or a body-contacted mode, and a passgate FET. A body of the contacted-body FET structure is connected to the drain of the passgate FET. Voltage can be applied to the passgate FET to either allow or restrict current flow through the passgate FET, to operate the contacted-body FET structure in body contacted mode or floating body mode. Data can be taken in each mode and compared to extract a floating body voltage.

### TECHNICAL FIELD

Embodiments of this invention relate generally to integrated circuits and, more particularly, to a silicon-on-insulator (SOI) body-contact pass gate structure for testing SOI field effect transistors (FETs).

### BACKGROUND

In silicon-on-insulator (SOI) devices such as metal oxide semiconductor field effect transistors (MOSFETs), the body of the device is disposed on an insulator rather than in a bulk wafer, and hence is “floating” as compared to conventional bulk devices. As a result, body leakage mechanisms are responsible for the steady state (resting) voltage of the body, and, unlike in bulk devices, the body voltage will change in response to the voltages applied to the source, drain and gate.

For accurate measurement of SOI currents with various body-charge states, it is useful to have a body-contacted (e.g., H-body or T-body) field effect transistors (FETs), characterized with fixed, known, body voltages, and with the body electrically floating. To enable body contacts, gates are formed in a ‘T’ shape or an ‘H’ shape, and are known as ‘H-body’ or ‘T-body’ FETs, respectively. When measuring the H-body or T-body FET in floating body mode, the capacitance of the associated cables, relays, probes, and other measurement apparatus can result in a relatively long time for the floating body to reach steady-state condition. This can be especially true for situations where the body currents are relatively small, for example, for measurements at low drain or low gate bias. This can lead to long test times, e.g., as long as 30 seconds per point, which can be economically prohibitive. An alternative approach is to provide separate floating body devices, with no wafer connection, and devices with body contacts wired to probes. This method has the draw back of introducing spurious mismatches between the two FETs, which in turn leads to inaccuracy of the inferred connection in body voltages.

### SUMMARY OF THE INVENTION

A circuit for testing a floating body field-effect transistor (FET), and a related method, are provided. Embodiments of this invention include a circuit including a contacted-body FET structure that can be operated in a floating body mode or a body-contacted mode, and a passgate FET. A body of the contacted-body FET structure is connected to the drain of the passgate FET. Voltage can be applied to the passgate FET to either allow or restrict current flow through the passgate FET, to operate the contacted- body FET structure in body contacted mode or floating body mode. Data can be taken in each mode and compared to extract a floating body voltage.

A first aspect of the invention provides a circuit for testing a floating body field-effect transistor (FET), the circuit comprising: a contacted-body FET structure having a source, a drain, a gate and a body, wherein the contacted-body FET structure can be operated in a floating body mode or a body-contacted mode; and a passgate FET having a source, a drain and a gate, wherein the body of the contacted-body FET structure is connected to the drain of the passgate FET.

A second aspect of the invention provides a test structure for testing a floating body field-effect transistor (FET), comprising: a semiconductor substrate having a silicon layer; a contacted-body field-effect transistor (FET) structure formed in the silicon layer, the contacted-body FET structure having a source, a drain, a gate and a body, wherein the contacted-body FET structure can be operated in a floating body mode or a body-contacted mode; and a passgate FET formed in the silicon layer, the passgate FET having a source, a drain and a gate, wherein the body of the contacted-body FET structure is electrically connected to the drain of the passgate FET.

A third aspect of the invention provides a method of testing a floating body field-effect transistor (FET), the method comprising: providing a structure including: a contacted-body FET structure having a source, a drain, a gate and a body, wherein the contacted-body FET structure can be operated in a floating body mode or a body-contacted mode; a passgate FET having a source, a drain and a gate, wherein the body of the contacted-body FET structure is connected to the drain of the passgate FET; and at least one of: (i) applying a first voltage to the gate of the passgate FET to allow current flow from the body to the source of the passgate FET such that the contacted-body FET structure is operated in body contacted mode, and (ii) applying a second voltage to the gate of the passgate FET to prevent current flow from the body to the source of the passgate FET such that the contacted-body FET structure is operated in floating body mode.

### BRIEF DESCRIPTION OF DRAWINGS

These and other features of this invention will be more readily understood from the following detailed description of the various aspects of the invention taken in conjunction with the accompanying drawings that depict various embodiments of the invention, in which:

FIG. 1 shows a circuit diagram of a circuit according to an embodiment of this invention.

FIGS. 2-5 show top views of various circuits according to embodiments of this invention.

It is noted that the drawings of the invention are not to scale. The drawings are intended to depict only typical aspects of the invention, and therefore should not be considered as limiting the scope of the invention. In the drawings, like numbering represents like elements between the drawings.

### DETAILED DESCRIPTION OF INVENTION

Embodiments of this invention include introducing a contacted body device, employing, for example, either H-body or T-body structures, with pass-gate access from the body to a probe pad. The pass-gate transistor can be a thick gate-oxide FET with low leakage, to provide maximum isolation in the floating body mode, i.e., when the pass-gate is electrically configured in a non-conducting state, or ‘off.’

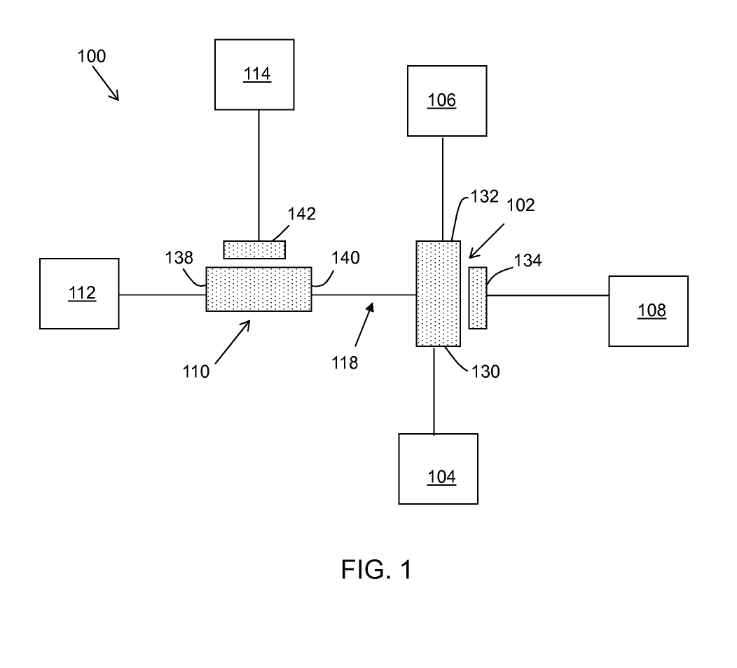

Turning to FIG. 1, a circuit diagram of a circuit 100 for testing a field-effect transistor (FET) according to an embodiment of this invention is shown. As shown in FIG. 1, circuit 100 includes a device under test, i.e., a contacted-body FET structure 102, which can be formed in a silicon layer of a semiconductor substrate (not shown). Contacted-body FET structure 102 has a selectable body mode (i.e., the body can be placed into a floating state during test, or the body voltage can be set to an externally controlled value). As understood by one of skill in the art, contacted-body FET structure 102 has a source region 130, a drain region 132 and a gate region 134. Contacted-body FET structure 102 further includes a body 118. Circuit 100 further includes a passgate FET 110 which can be formed in the silicon layer of the semiconductor substrate (not shown). Passgate FET 110 also has a source region 138, a drain region 140 and a gate region 142. As discussed in more detail herein, body 118 of contacted-body FET structure 102 is electrically connected to drain region 140 of passgate FET 110.

As shown in FIG. 1, in one embodiment, a plurality of probe pads are electrically connected to contacted-body FET structure 102, i.e., a first probe pad 104 connected to source region 130, a second probe pad 106 connected to drain region 132 and a third probe pad 108 connected to gate region 134. In addition, at least two probe pads are electrically connected to passgate FET 110, i.e., a fourth probe pad 112 connected to source region 138 of passgate FET 110 and a fifth probe pad 114 connected to gate region 142 of passgate FET 110. In addition, body 118 of contacted-body FET structure 102 is electrically connected to drain region 140 of passgate FET 110.

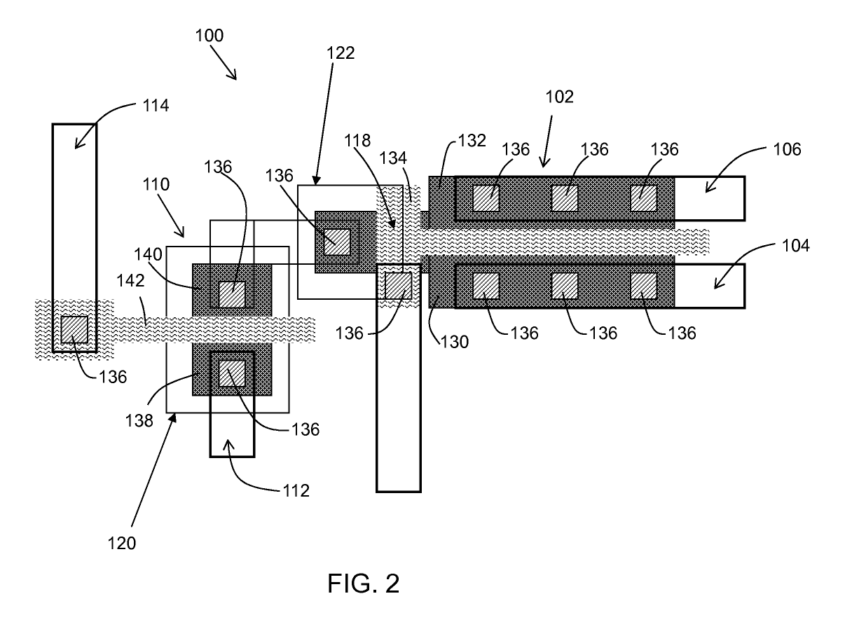

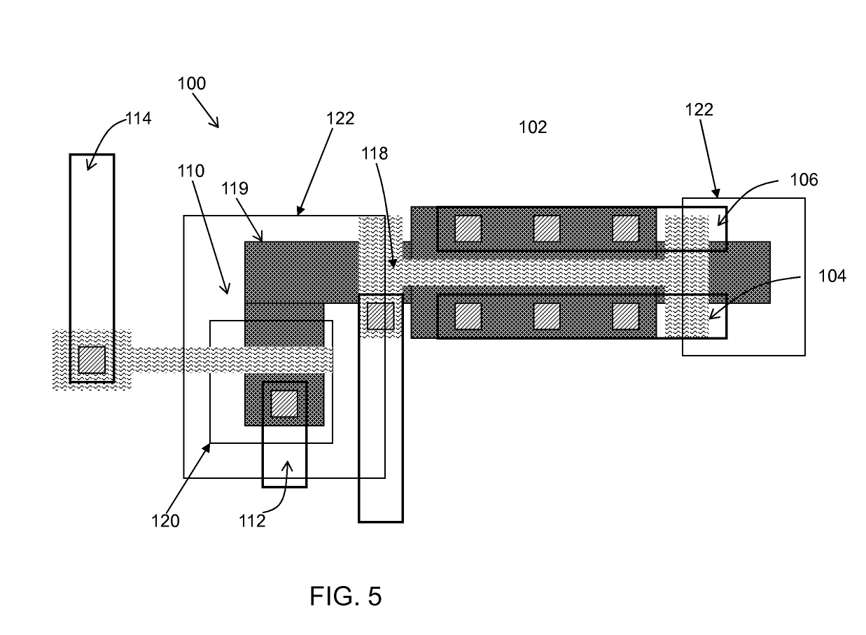

A top view of a physical design to realize circuit 100 according to an embodiment of this invention is shown in FIG. 2. As shown in FIG. 2, in this embodiment, contacted-body FET structure 102 is referred to as a T-body FET because gate region 134 is generally T-shaped. Alternatively, an H-body FET can be employed as shown in FIG. 5. It is understood that although it is difficult to show in the top views of FIGS. 2-5, body 118 of FET 102 refers to the area under gate region 134 indicated by the arrow.

As known in the art, contacted-body FET structure 102 and passgate FET 110 both include a plurality of contacts 136, for contacting the various portions of FETs 102, 110. As understood in the art, each probe pad discussed herein can be connected to a contact in the respective region it is connected to. For example, probe pad 114 can be connected to a contact 136 in gate region 142, and probe pad 112 can be connected to a contact 136 in source region 138.

In this configuration, shown in FIG. 2, a doping mask having a mask opening 122 is used such that a portion of body 118 of contacted-body FET structure 102 under mask opening 122 can be doped as desired. In one embodiment, the device under test (i.e., contacted-body FET structure 102) is an n-type doped FET, and therefore the doping mask would be a p-type doping mask such that the area under mask opening 122, i.e., body 118, would be doped p-type. With an n-type doped FET 102 (i.e., NFET 102) and a p-type doped body 118, source and drain regions 138, 140 of passgate FET 110 would then be doped n-type. However, it is understood that the polarity of each device can be reversed as desired. For example, a p-type contacted-body FET structure 102 can be the device under test, with an n-type doping mask opening 122 (and therefore n-type doped body 118) and then source and drain regions of passgate FET 110 would be doped p-type.

As shown in FIG. 2, contacted-body FET structure 102 and passgate FET 110 are connected via body 118 of contacted-body FET structure 102, which has been doped as desired by using mask opening 122. In one embodiment, a contact 136 to body 118 is electrically connected to a contact 136 to drain region 140 of passgate FET 110 via traditional connection means, such as wires. As such, body 118 of floating body 102 is electrically connected to drain region 140 of passgate FET 110.

Testing of contacted-body FET structure 102 can comprise compiling data from the circuit while passgate FET 110 is operated in either a floating body mode or a body contacted mode. Generally, voltage is applied to gate region 142 of passgate FET 110 as necessary to either turn “on” or “off” passgate FET 110, such that contacted-body FET structure 102 is in either contacted body mode or floating body mode, respectively.

To operate contacted-body FET structure 102 in body contacted mode, a first voltage (i.e., above a threshold voltage for passgate FET 110) is applied to passgate FET 110 (e.g., via probe pad 114) so that passgate FET 110 is “on” which allows current flow through gate region 142 (e.g., from probe pad 114 to probe pad 112) such that FET structure 102 is in body-contacted mode. When passgate FET 110 is “on” and current is flowing through passgate FET 110, a plurality of known body voltages, higher than the threshold voltage, can be applied to gate region 142.

To operate contacted-body FET structure 102 in floating body mode, a second voltage (i.e., negative or zero) is applied to passgate FET 110 (e.g., via probe pad 114) so that passgate FET 110 is “off” which prevents current flow through gate region 142 (e.g., from probe pad 114 to probe pad 112) such that FET structure 102 is “floating.” As such, voltage can be applied to passgate FET 110 as desired to either allow or restrict current flow between passgate FET 110 and contacted-body FET structure 102.

In one embodiment, data is compiled while contacted-body FET structure 102 is in each mode, i.e., contacted-body mode and floating body mode. Then, data received while passgate FET 110 is “off” and in floating body mode can then be compared with data received while passgate FET 110 is “on” and in body contacted mode, in order to extract a floating body voltage of floating body FET 102. In particular, the source and drain currents of contacted-body FET structure 102 are measured over a range of gate-to-source voltages (Vgs) and drain-to-source voltages (Vds) with FET 102 in floating body mode. Similarly, the source and drain currents are measured over a similar range of gate-to-source voltages (Vgs) and drain-to-source voltages (Vds) with FET 102 in contacted-body mode. However, in contacted-body mode, these measurements are repeated over a range of applied body-to-source voltages (Vbs). For a given set of Vgs and Vds common to both modes, one of skill in the art can algorithmically identify which Vbs yields the same source and drain currents in contacted body mode as measured in floating body mode, and thus extract the floating body voltage. Because circuit 100, according to embodiments of this invention, uses the same, identical FET 102 in both modes, as opposed to prior art systems that use a separate floating-body FET and a separate contacted-body FET, the incidental mismatches between separate FETs inherent in the prior art systems are eliminated.

In contrast to prior systems, which would connect a probe pad directly to a first FET operated in a first mode, and a probe pad directly to a second FET operated in a second mode, in circuit 100, passgate FET 110 is included between the device under test (FET 102) and the voltage being applied (e.g., through probe pad 114) during the test. In this way, the same FET 102 can be used to compile data in both floating body mode and contacted body mode.

As also shown in FIG. 2, in one embodiment, a mask 120 can be used to introduce an extra layer of gate dielectric, e.g., silicon dioxide, where gate region 142 crosses the silicon of passgate FET 110 to reduce leakage. In other words, even when no voltage is applied to probe pad 114, i.e., passgate FET 110 is “off”, some leakage of voltage is possible. A gate dielectric, e.g., a thick oxide mask, can help reduce this leakage.

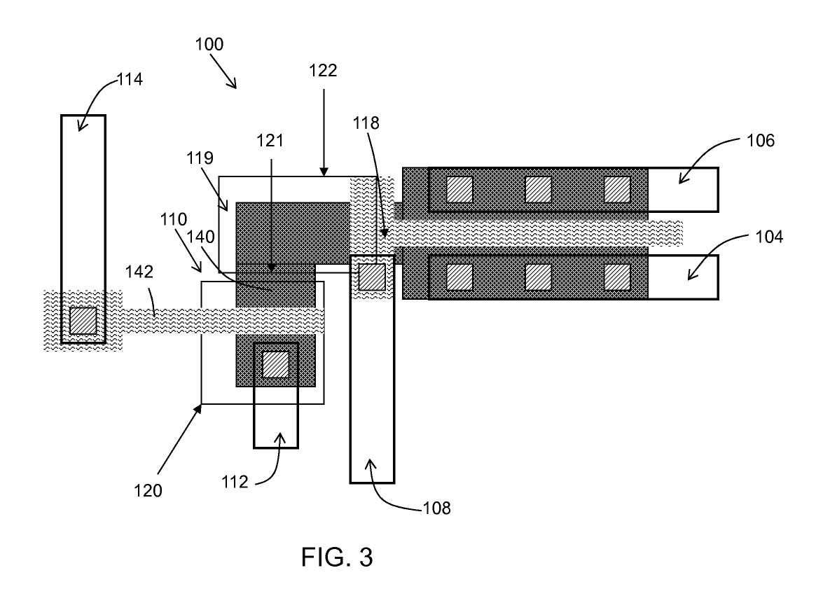

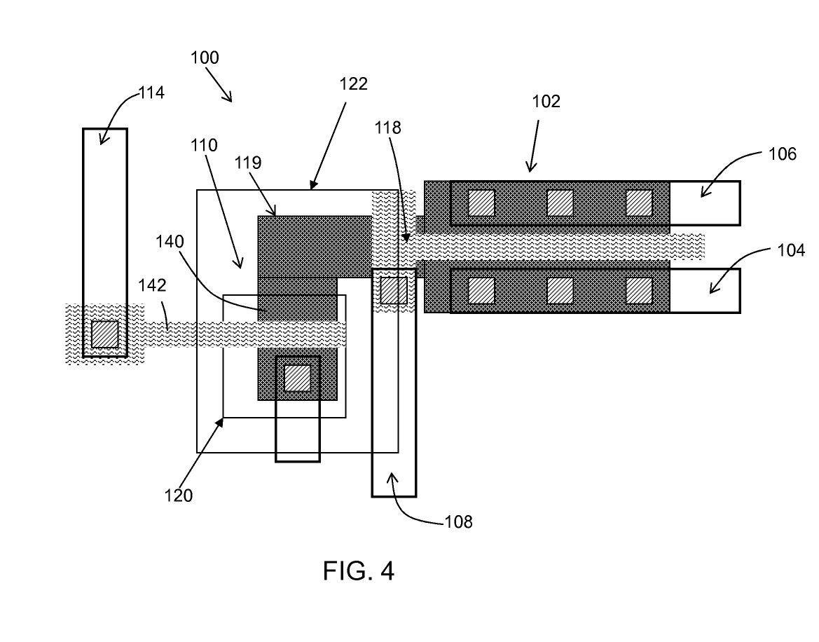

FIGS. 3 and 4 show alternative configurations of circuit 110 with alternative connections between passgate FET 110 and contacted-body FET structure 102. Turning to FIG. 3, a configuration of circuit 100 using a silicon interconnect 119 to connect passgate FET 110 and contacted-body FET structure 102 is shown. In other words, in this embodiment, body 118 is connected to drain region 140 of passgate FET 110 through silicon interconnect 119. In one embodiment, silicon interconnect 119 can comprise a continuous single-crystal silicon connection having two regions of opposite doping polarity. In one embodiment, mask opening 122 is used to p-type dope body 118, while passgate FET 110 and source/drain regions 138, 140 of passgate FET 110 are n-type doped. Therefore, a butted junction is formed in the silicon where the p-type doped region meets the n-type doped region. The polarity of these regions can be reversed in keeping with this embodiment, as long as the region adjacent to passgate FET 110 has the same doping polarity as drain region 140 of passgate FET 110, and the region adjacent FET 102 has the same doping polarity as body 118 of FET 102. A butted junction region 121, bridged by a metal silicide, e.g., a nickel silicide or cobalt silicide, is formed within silicon interconnect 119, between n-type doped and p-type doped regions. For example, the continuous silicon connection can be p-type doped silicon while passgate FET 110 can be n-type doped. In the configuration shown in FIG. 3, silicon interconnect 119 between body 118 and passgate FET 110 eliminates at least two contacts (and corresponding wires) present in the configuration shown in FIG. 2, since passgate FET 110 is directly wired through the silicon to body 118.

Turning to FIG. 4, a silicon interconnect 119 to connect passgate FET 110 and contacted-body FET structure 102, similar to the configuration shown in FIG. 3, is shown. Again, it is desired that any associated leakage currents introduced by passgate FET 110 be negligible in comparison with the currents responsible for establishing body voltage when contacted-body FET structure 102 is in floating body mode, i.e., when passgate FET 110 is in the ‘off’ state. Hence, in the embodiment shown in FIG. 4, similar to other embodiments, a mask 120 is employed to introduce a gate dielectric in passgate FET 110, which is physically thicker in comparison to that in contacted-body FET structure 102. This thicker gate dielectric provides for reduced current leakage from drain region 140 to gate region 142 of passgate FET 110, which, if too large, could interfere with accurate operation of contacted-body FET structure 102 in the floating-body mode. In one example, mask 120 is used to introduce an extra layer of gate dielectric, e.g., silicon dioxide, selectively under a gate electrode of passgate FET 110.

The embodiment shown in FIG. 4 further includes a similarly doped passgate FET 110 and body 118. In contrast to the embodiments shown in FIGS. 2 and 3, in FIG. 4, mask opening 122 is large enough such that body 118 and passgate FET 110 are both doped p-type (or n-type, depending on the polarity of the other components in circuit 100). Therefore, source and drain regions 138, 140 of passgate FET 110 and body 118 are similarly doped.

As discussed above, as shown in FIG. 5, contacted-body FET structure 102 can also comprise an H-body FET. While the arrangement shown in FIG. 5 shows an H-body FET 102 with silicon interconnect 119 and mask opening 122 used to create a similarly doped passgate FET 110 and body 118, similar to the arrangement shown in FIG. 4, it is understood that an H-body FET 102 can be used in any of the arrangements disclosed herein. As shown in FIG. 5, when using an H-body FET 102, mask openings 122 can be used to dope each end of the H-body shape as desired. For example, if H-body FET 102 is an n-type doped FET, the doping mask would be a p-type doping mask such that the area under mask openings 122 would both be doped p-type.

It is understood that while probe pads are discussed herein as a means of electrically contacting a structure, such as passgate FET 110 or FET 102, one of ordinary skill in the art would understand that any known means of electrically contacting a structure could be used in accordance with the embodiments discussed herein. For example, a circuit can be further integrated on a test die which can either multiplex connecting pads leading off the die to passgate FET 110 and FET 102, or can be digitally accessed to apply voltages on the die to passgate FET 110 and FET 102, and to convert terminal currents to a digital stream of data, and transmit such data off the die for analysis.

The foregoing description of various aspects of the invention has been presented for purposes of illustration and description. It is not intended to be exhaustive or to limit the invention to the precise form disclosed, and obviously, many modifications and variations are possible. Such modifications and variations that may be apparent to a person skilled in the art are intended to be included within the scope of the invention as defined by the accompanying claims.

What is claimed is:

1. A circuit for testing a floating body field-effect transistor (FET), the circuit comprising:
a contacted-body FET structure having a source, a drain, a gate and a body, wherein the contacted-body FET structure can be operated in a floating body mode or a body-contacted mode; and
a passgate FET having a source, a drain and a gate, wherein the body of the contacted-body FET structure is connected to the drain of the passgate FET, and the body of the contacted-body FET is electrically connected to the drain of the passgate FET by a silicon interconnect.

2. The circuit of claim 1, further comprising:
a first probe pad connected to the source of the contacted-body FET structure;
a second probe pad connected to the drain of the contacted-body FET structure;
a third probe pad connected to the gate of the contacted-body FET structure;
a fourth probe pad connected to the source of the passgate FET; and
a fifth probe pad connected to the gate of the passgate FET.

3. The circuit of claim 1, wherein the contacted-body FET structure and the passgate FET are n-type FETs, and at least a portion of the body of the contacted-body FET structure is doped p-type.

4. The circuit of claim 1, wherein the silicon interconnect comprises a region of single-crystal silicon.

5. The circuit of claim 1, wherein the passgate FET and the contacted-body FET structure are of opposite polarity type.

6. The circuit of claim 1, further comprising a thick oxide mask on the gate of the passgate FET.

7. The circuit of claim 1, wherein the passgate FET is a low-leakage, thick gate dielectric device.

8. A test structure for testing a floating body field-effect transistor (FET), comprising:
a semiconductor substrate having a silicon layer;
a contacted-body field-effect transistor (FET) structure formed in the silicon layer, the contacted-body FET structure having a source, a drain, a gate and a body, wherein the contacted-body FET structure can be operated in a floating body mode or a body-contacted mode; and
a passgate FET formed in the silicon layer, the passgate FET having a source, a drain and a gate, wherein the body of the contacted-body FET structure is electrically connected to the drain of the passgate FET, and the body of the contacted-body FET structure is electrically connected to the drain of the passgate FET by a silicon interconnect.

9. The test structure of claim 8, further comprising:
a first probe pad connected to the source of the contacted-body FET structure;
a second probe pad connected to the drain of the contacted-body FET structure;
a third probe pad connected to the gate of the contacted-body FET structure;
a fourth probe pad connected to the source of a passgate FET; and
a fifth probe pad connected to the gate of the passgate FET.

10. The test structure of claim 9, wherein the contacted-body FET structure and the passgate FET are n-type FETs, and at least a portion of the body of the contacted-body FET structure is doped p-type.

11. The test structure of claim 8, wherein the silicon interconnect comprises a region of single-crystal silicon.

12. The test structure of claim 8, wherein the passgate FET and the contacted-body FET structure are of opposite polarity type.

13. The test structure of claim 8, further comprising a thick oxide mask on the gate of the passgate FET.

14. A method of testing a floating body field-effect transistor (FET), the method comprising:
providing a structure including:
a contacted-body FET structure having a source, a drain, a gate and a body, wherein the contacted-body FET structure can be operated in a floating body mode or a body-contacted mode;
a passgate FET having a source, a drain and a gate, wherein the body of the contacted-body FET structure is electrically connected to the drain of the passgate FET via a silicon interconnect; and
at least one of: (i) applying a first voltage to the gate of the passgate FET to allow current flow from the body to the source of the passgate FET such that the contacted-body FET structure is operated in body contacted mode, and (ii) applying a second voltage to the gate of the passgate FET to prevent current flow from the body to the source of the passgate FET such that the contacted-body FET structure is operated in floating body mode.

15. The method of claim 14, wherein the structure further includes:
a first probe pad connected to the source of the contacted-body FET structure;
a second probe pad connected to the drain of the contacted-body FET structure;
a third probe pad connected to the gate of the contacted-body FET structure;
a fourth probe pad connected to the source of a passgate FET; and
a fifth probe pad connected to the gate of the passgate FET.

16. The method of claim 15, wherein the applying the first voltage includes applying the first voltage to the fifth probe pad to allow current flow from the body to the fourth probe, and wherein the applying the second voltage includes applying the second voltage to the fifth probe pad to prevent current flow from the body to the fourth probe pad.

17. The method of claim 14, wherein the contacted-body FET structure is operated in body contacted mode and in floating body mode, the method further comprising:
receiving body contacted data while contacted-body FET structure is operated in body contacted mode;
receiving floating body data while contacted-body FET structure is operated in floating body mode; and
comparing the body contacted data and the floating body data to extract a floating body voltage value.

18. The method of claim 14, wherein the providing further includes providing the contacted-body FET structure and the passgate FET as n-type FETs, and p-type doping at least a portion of the body of the contacted-body FET structure.

19. The method of claim 14, wherein the providing further includes providing a thick oxide mask on the gate of the passgate FET.

20. The method of claim 14, wherein the first voltage comprises a zero or negative voltage and the second voltage comprises a voltage higher than a threshold voltage of the passgate FET.
